(19) United States
(12) Patent Application Publication
(10) Pub. No.: US 2019/0241696 A1
(43) Pub. Date: Aug. 8, 2019

(54) THERMOSETTING EPOXY RESIN SHEET FOR ENCAPSULATING SEMICONDUCTOR, SEMICONDUCTOR APPARATUS, AND METHOD FOR MANUFACTURING SAME

(71) Applicant: SHIN-ETSU CHEMICAL CO., LTD., Tokyo (JP)

(72) Inventors: Yoshihiro TSUTSUMI, Annaka-shi (JP); Kazuaki SUMITA, Annaka-shi (JP); Kenji HAGIWARA, Annaka-shi (JP)

(73) Assignee: SHIN-ETSU CHEMICAL CO., LTD., Tokyo (JP)

(21) Appl. No.: 16/256,300

(22) Filed: Jan. 24, 2019

(30) Foreign Application Priority Data
Feb. 5, 2018 (JP) 2018-018443

(51) Int. Cl. C08G 59/38; C08G 59/50; C08G 59/62; C08K 3/36; H01L 33/56

(52) U.S. Cl. CPC C08G 59/38; C08G 59/5073; H01L 33/56; C08K 3/36; C08G 59/62

(57) ABSTRACT

This is to provide a thermosetting epoxy resin sheet for encapsulating a semiconductor which is excellent in flexibility in a state before curing, and good in handling property, while maintaining a high glass transition temperature after curing, and also excellent in storage stability and moldability. The thermosetting epoxy resin sheet for encapsulating a semiconductor is a material which comprises a composition containing (A) a bisphenol A type epoxy resin and/or a bisphenol F type epoxy resin each having crystallinity, (B) a polyfunctional type epoxy resin which is solid at 25° C. and other than the Component (A), (C) a phenol compound having two or more phenolic hydroxyl groups in one molecule, (D) an inorganic filler, and (E) an imidazole-based curing accelerator having a melting point of 170° C. or higher, and one or two hydroxymethyl groups in one molecule, being molded in a sheet form.

### TECHNICAL FIELD

The present invention relates to a thermosetting epoxy resin sheet for encapsulating a semiconductor, and a semiconductor apparatus using the same.

### BACKGROUND ART

There is a semiconductor package obtained by encapsulating a semiconductor device(s) with resin as an electronic part used in an electronic apparatus. The semiconductor package has conventionally been manufactured by transfer molding of a tablet state epoxy resin composition in general. On the other hand, in recent years, with miniaturization and weight reduction of electronic devices, high-density mounting of electronic parts on wiring boards is required, and miniaturization, thinning and weight reduction of semiconductor packages are also advanced.

With the advancement of thinning of semiconductor packages and the like, there are cases where conventional transfer molding cannot deal with it. In addition, a molding method that changes to transfer molding has been studied for the purpose of improving productivity by increasing the number to be taken. For example, when molding into a large substrate with increase in the number to be taken is performed, the problem of warpage is liable to occur, and the amount of an inorganic filler in the encapsulating material tends to increase in order to suppress warpage. Due to such high filling of the inorganic filler, the melt viscosity of the resin becomes high at the time of transfer molding, and filling property lowers. As a result, there occur poor filling, voids remaining in the molded product, wire flow (deformation or breakage of the bonding wire), increase in die shift, and the like, and the quality of the molded product is lowered.

Thus, application of a compression molding method has been studied as a encapsulating method to replace transfer molding, and not only a liquid state but also a sheet state encapsulating material has been studied variously (Patent Documents 1 and 2). However, these sheet state encapsulating materials use ordinary epoxy resin and phenol curing agent, and even if it is molded into a sheet shape, if it is in the uncured or semi-cured state, it is poor in flexibility which easily generates cracks and chips, so that there is a problem in handling properties.

In order to solve these problems, a sheet material to which a styrene-isobutylene type thermoplastic resin is added has been reported, but this styrene-isobutylene type thermoplastic resin is not easy to melt by heating and mixing, and is easily separated so that there is a problem that not only the production of the sheet is difficult but also the intended effect is difficult to obtain (Patent Document 3). Moreover, even if a flexibility imparting agent for improving crack resistance of the cured product is added, there is no effect in imparting flexibility to the sheet (Patent Documents 4 and 5).

In order to solve these problems, it has been reported that flexibility is greatly improved by using a composition which uses a biphenyl type epoxy resin which is a crystalline epoxy resin as a composition emphasizing flexibility (Patent Document 6). On the other hand, longer working life and storage stability are desired for sheet materials due to limitation of molding time and the like. Simply reducing the amount of the curing accelerator is excellent in storage stability but it becomes poor in curability. Therefore, it has been desired to develop a sheet material which satisfies both requirements, but the above composition is insufficient as a sheet material which satisfies both requirements.

In addition, as a disadvantage of these sheet materials, due to the properties of the epoxy resin and phenolic resin to be used, the glass transition temperature is 120° C. or lower which is lower as compared with that of the general thermosetting epoxy resin composition for encapsulating a semiconductor. On the other hand, in recent years, since the high reliability tends to be more desired, the characteristics of the sheet material are still insufficient, and little is known about those satisfying the current material requirements.

### CITATION LIST

### Patent Literature

Patent Document 1: JP Hei. 8-73621A

Patent Document 2: JP 2006-216899A

Patent Document 3: JP 2016-213391A

Patent Document 4: JP 2016-108387A

Patent Document 5: JP 2016-108388A

Patent Document 6: JP 2016-9814A

### SUMMARY OF INVENTION

### Technical Problem

The present invention has been made to solve the problems, and an object thereof is to provide a thermosetting epoxy resin sheet for encapsulating a semiconductor which is excellent in flexibility in a state before curing, and good in handling property, while maintaining a high glass transition temperature after curing, and also excellent in storage stability and moldability.

### Solution to Problem

In order to achieve the object, according to the present invention, it is provided a thermosetting epoxy resin sheet for encapsulating a semiconductor which comprises a composition containing

(A) a bisphenol A type epoxy resin and/or a bisphenol F type epoxy resin each having crystallinity,
(B) a polyfunctional type epoxy resin which is solid at 25° C. and other than the Component (A),
(C) a phenol compound having two or more phenolic hydroxyl groups in one molecule,
(D) an inorganic filler, and
(E) an imidazole-based curing accelerator having a melting point of 170° C. or higher, and one or two hydroxymethyl groups in one molecule, being molded in a sheet form.

When such a thermosetting epoxy resin sheet for encapsulating a semiconductor is employed, it becomes a thermosetting epoxy resin sheet for encapsulating a semiconductor which is excellent in flexibility in a state before curing, and good in handling property, while maintaining a high glass transition temperature after curing, and also excellent in storage stability and moldability.

In addition, it is preferable that the Component (B) is a trisphenol alkane type epoxy resin.

When such Component (B) is employed, it becomes a thermosetting epoxy resin sheet for encapsulating a semiconductor having a higher glass transition temperature and more excellent low warpage.

In addition, it is preferable that the Component (E) is represented by the following general formula (1),

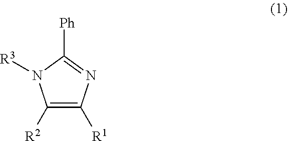

wherein, each of R¹ and R² independently represents any of a hydrogen atom, a methyl group, an ethyl group, a hydroxymethyl group or a phenyl group, at least one of them is a hydroxymethyl group; R³ represents a hydrogen atom, a methyl group, an ethyl group, a phenyl group or an allyl group; and Ph represents a phenyl group.

When such Component (E) is employed, it becomes a thermosetting epoxy resin sheet for encapsulating a semiconductor having more excellent storage stability and a higher glass transition temperature.

In addition, it is preferable that the Component (D) contains silica.

When such Component (D) is employed, it becomes a thermosetting epoxy resin sheet for encapsulating a semiconductor having more excellent strength and low warpage.

Also, it is preferable that the thermosetting epoxy resin sheet for encapsulating a semiconductor is a material in which a cured product thereof obtained by pressure molding with a molding pressure of 6.9 N/mm² at 175° C. for 180 seconds, and then, secondary curing at 180° C. for 4 hours, which has a glass transition temperature measured by thermomechanical analysis (TMA) of 150° C. or higher.

When such a thermosetting epoxy resin sheet for encapsulating a semiconductor is employed, it can be made a material more excellent in heat resistant reliability.

Further, it is preferable that the thermosetting epoxy resin sheet for encapsulating a semiconductor has a deflection amount of the sheet of 25 mm or more in a three-point bending test in an uncured state.

When such a thermosetting epoxy resin sheet for encapsulating a semiconductor is employed, it can be made a material excellent in flexibility in a state before curing more certainly, and having good handling property.

In the present invention, it is provided a semiconductor apparatus in which a semiconductor device(s) is/are encapsulated by the thermosetting epoxy resin sheet for encapsulating a semiconductor.

When such a semiconductor apparatus is employed, it becomes a semiconductor apparatus in which the semiconductor device(s) is/are well encapsulated, and is free from voids, wire flow, and die shift.

Also, according to the present invention, it is provided a method for manufacturing a semiconductor apparatus in which a semiconductor device(s) is/are encapsulated using the thermosetting epoxy resin sheet for encapsulating a semiconductor.

When such a method for manufacturing the semiconductor apparatus is employed, the sheet is softened and melted by heating at a temperature equal to or lower than the curing temperature of the thermosetting epoxy resin sheet for encapsulating a semiconductor, and encapsulating can be done by following the shape of the semiconductor device(s).

In addition, in encapsulating the semiconductor device(s), it is preferable to soften and melt the sheet while heating to encapsulate the semiconductor device(s) under pressure and/or under reduced pressure.

When such a method for manufacturing the semiconductor apparatus is employed, it is possible to further improve adhesion between the thermosetting epoxy resin sheet for encapsulating a semiconductor following the shape of the semiconductor device(s) by softening and melting and the semiconductor device(s).

### Advantageous Effects of Invention

As mentioned above, when the thermosetting epoxy resin sheet for encapsulating a semiconductor of the present invention is employed, it becomes a thermosetting epoxy resin sheet for encapsulating a semiconductor which is excellent in flexibility in a state before curing, and good in handling property, while maintaining a high glass transition temperature after curing, and also excellent in storage stability and moldability. Also, when the semiconductor apparatus of the present invention in which a semiconductor device(s) is/are encapsulated by such a thermosetting epoxy resin sheet for encapsulating a semiconductor of the present invention is employed, the semiconductor device(s) is/are well encapsulated to give a semiconductor apparatus which is free from voids, wire flow, and die shifting. Further, when the method for manufacturing a semiconductor apparatus of the present invention using the thermosetting epoxy resin sheet for encapsulating a semiconductor of the present invention is employed, the sheet is softened and melted by heating at a temperature equal to or lower than the curing temperature of the thermosetting epoxy resin sheet for encapsulating a semiconductor, and can encapsulate following the shape of the semiconductor device(s) and adhesion between the sheet and the semiconductor device(s) can be further improved.

### BRIEF DESCRIPTION OF DRAWING

FIG. 1 is an example of the load-deflection amount curve used to measure the deflection amount of a sheet.

### DESCRIPTION OF EMBODIMENTS

As mentioned above, it has been desired to develop a thermosetting epoxy resin sheet for encapsulating a semiconductor which is excellent in flexibility in a state before curing, and good in handling property, while maintaining a high glass transition temperature after curing, and also excellent in storage stability and moldability.

The present inventors have intensively studied to achieve the above objects, and as a result, they have found that the above subjects can be achieved by a thermosetting epoxy resin sheet produced by a composition containing a specific combination of an epoxy resin and an imidazole curing accelerator, whereby the present invention has completed.

That is, the present invention is directed to a thermosetting epoxy resin sheet for encapsulating a semiconductor which comprises a composition containing

(A) a bisphenol A type epoxy resin and/or a bisphenol F type epoxy resin each having crystallinity,
(B) a polyfunctional type epoxy resin which is solid at 25° C. and other than the Component (A),
(C) a phenol compound having two or more phenolic hydroxyl groups in one molecule,
(D) an inorganic filler, and
(E) an imidazole-based curing accelerator having a melting point of 170° C. or higher, and one or two hydroxymethyl groups in one molecule, being molded in a sheet form.

### <Thermosetting Epoxy Resin Sheet for Encapsulating Semiconductor>

The thermosetting epoxy resin sheet for encapsulating a semiconductor of the present invention is a material in which the composition containing the Components (A) to (E) is molded in a sheet state. In the following, each component will be explained in more detail.

### (A) Bisphenol Type Epoxy Resin Having Crystallinity

As (A) the bisphenol type epoxy resin having crystallinity to be used in the present invention, a bisphenol A type epoxy resin and/or a bisphenol F type epoxy resin each having crystallinity is/are used. By using such a bisphenol type epoxy resin having crystallinity, it is possible not only to impart flexibility to the sheet when formed into a sheet but also to have good moldability even if it is highly filled with an inorganic filler which is a Component (D) mentioned later. In addition, Component (A) can be used without being limited by molecular weight and the like as long as it is a bisphenol A type epoxy resin and/or a bisphenol F type epoxy resin each having crystallinity, and it is preferably a bisphenol A type epoxy resin having crystallinity.

Examples of the bisphenol type epoxy resin having crystallinity that is Component (A) include, for example, commercially available products such as YL-6810 (manufactured by Mitsubishi Chemical Corporation), YSLV-70XY, and YSLV-80XY (both manufactured by Nippon Steel & Sumikin Chemical Co., Ltd.) and these can be used.

The amount of (A) the bisphenol type epoxy resin having crystallinity to be blended is preferably in the range of 12 to 35 parts by mass, more preferably 14 to 33 parts by mass, further preferably 15 to 30 parts by mass relative to the sum of 100 parts by mass of the polyfunctional type epoxy resin which is Component (B) and is a solid at 25° C. other than Component (A) and the phenol compound having two or more phenolic hydroxyl groups in one molecule which is Component (C) mentioned later. If it is 12 parts by mass or more, sufficient flexibility can be imparted to the sheet obtained by molding, while if it is 35 parts by mass or less, there is no fear of becoming tackiness strong, lowering holding power as a sheet or becoming too low glass transition temperature of the resin constituting the sheet while maintaining sufficient flexibility. In the present invention, “a resin having crystallinity” refers to a resin which becomes a liquid at a temperature of the melting point or higher and indicating high fluidity.

(B) Polyfunctional Type Epoxy Resin which is Solid at 25° C. and Other than the Component (A)

Component (B) used in the present invention is a polyfunctional type epoxy resin which is solid at 25° C. and other than the Component (A). When the Component (B) is used for the thermosetting epoxy resin sheet for encapsulating a semiconductor of the present invention, high glass transition temperature or low warpage can be realized so that it is used. Here, the “polyfunctional type epoxy resin” refers to an epoxy resin having three or more epoxy groups in one molecule. As the polyfunctional type epoxy resin, a structure represented by the following general formula (2) is particularly preferable.

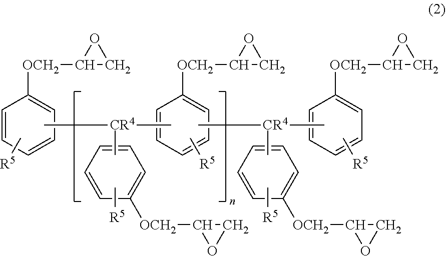

In the general formula (2), R⁴'s each independently represents a hydrogen atom or a monovalent hydrocarbon group having 1 to 6 carbon atoms. Specific examples of R⁴ include a hydrogen atom, a methyl group, an ethyl group, an n-propyl group, an isopropyl group, an n-butyl group, an isobutyl group, a t-butyl group, an n-pentyl group, a neopentyl group, an n-hexyl group, a cyclohexyl group, a phenyl group, and the like, and preferably a hydrogen atom. R⁵'s each independently represents a hydrogen atom, a methyl group or an ethyl group, and preferably a hydrogen atom. A repeating unit “n” is an integer of 0 to 6, and preferably 0 to 3.

As the Component (B) to be used in the present invention, a trisphenol alkane type epoxy resin such as a trisphenol methane type epoxy resin and a trisphenol propane type epoxy resin is particularly preferable.

As the Component (B) to be used in the present invention, from the viewpoint of improving handling property including tackiness of the sheet, it is preferable that the softening point measured by the ring and ball method mentioned in JIS K 7234: 1986 or the melting point measured by the differential scanning calorimetry (DSC) method is in the range of 50 to 120° C.

### (C) Phenol Compound Having Two or More Phenolic Hydroxyl Groups in One Molecule

The phenol compound having two or more phenolic hydroxyl groups in one molecule which is Component (C) is used as a curing agent of the bisphenol A type epoxy resin and/or a bisphenol F type epoxy resin each having crystallinity which is Component (A), and the polyfunctional type epoxy resin which is solid at 25° C. and other than the Component (A) which is Component (B), and those generally and conventionally known material may be used as long as it has two or more, preferably three or more phenolic hydroxyl groups in one molecule. Examples of such Component (C) include, for example, a phenol novolac resin, a cresol novolac resin, a phenol aralkyl resin, a naphthol aralkyl resin, a terpene-modified phenolic resin, a dicyclopentadiene-modified phenolic resin, and the like, and these may be used singly or as a mixture thereof. These phenolic resins can be used without limitation to the molecular weight, the softening point, the amount of the hydroxyl groups or the like, and those having low softening point and relatively low viscosity are preferable.

The amount of Component (C) is preferably such that the equivalent ratio of the phenolic hydroxyl groups in Component (C) is 0.5 to 2.0 relative to the total amount of epoxy groups in Component (A) and Component (B), more preferably an amount of 0.7 to 1.5. If the equivalent ratio is 0.5 or more and 2.0 or less, there is no fear of lowering curability, mechanical characteristics and the like.

### (D) Inorganic Filler

The inorganic filler which is Component (D) is blended in order to increase the strength of the thermosetting epoxy resin sheet for encapsulating a semiconductor of the present invention. As the inorganic filler of Component (D), those generally blended in the epoxy resin composition or the silicone resin composition can be used. Examples thereof include silica such as spherical silica, fused silica and crystalline silica, inorganic nitrides such as silicon nitride, aluminum nitride and boron nitride, alumina, glass fibers and glass particles, and it is preferable that Component (D) contains silica in the points of excellent reinforcing effect and capable of suppressing warpage of the resulting cured product.

An average particle size and shape of the inorganic filler of Component (D) are not particularly limited, and the average particle size is preferably 0.1 to 40 μm, and more preferably 0.5 to 40 μm. In the present invention, the average particle size is a value obtained as a mass average value D₅₀ (or median diameter) in the particle size distribution measurement by a laser beam diffraction method.

From the viewpoint of increasing fluidity of the epoxy resin composition constituting the sheet at the time of producing the thermosetting epoxy resin sheet for encapsulating a semiconductor of the present invention, a material in which inorganic fillers with a plural particle size ranges are combined may be used as Component (D). In such a case, spherical silica of a fine region of 0.1 to 3 μm, a medium particle size region of 3 to 7 μm, and a coarse region of 10 to 40 μm are preferably used in combination, and as a result of combining these, it is more preferable that the average particle size of the whole Component (D) is in the range of 0.5 to 40 μm. In order to further increase fluidity, it is preferable to use spherical silica having larger average particle size.

On the other hand, when a semiconductor device(s) is/are encapsulated with a thermosetting epoxy resin sheet for encapsulating a semiconductor, molding is often performed by compression molding or lamination molding, and mold underfill (MUF) property is often required. From the viewpoint of improving the MUF property in the present invention, it is preferable to use spherical silica having an average particle size of 2 to 6 μm and a top cut size of 10 to 20 μm.

As the inorganic filler of Component (D), a material in which it is surface treated by a coupling agent of Component (I) mentioned later may be blended to strengthen the bonding strength with the resin components of Components (A), (B), and (C).

A filling amount of the inorganic filler of Component (D) is preferably 75 to 92 parts by mass, and more preferably 80 to 91 parts by mass relative to 100 parts by mass of the composition. If it is 75 parts by mass or more, sufficient strength can be imparted to the thermosetting epoxy resin sheet for encapsulating a semiconductor, while if it is 92 parts by mass or less, there is no fear of generating defective filling due to thickening and failure such as peeling in the semiconductor apparatus by losing flexibility, or the like.

### (E) Imidazole-Based Curing Accelerator Having Melting Point of 170° C. or Higher, and One or Two Hydroxymethyl Groups in One Molecule

Component (E) to be used in the present invention is an imidazole-based curing accelerator having a melting point of 170° C. or higher, and one or two hydroxymethyl groups in one molecule. This Component (E) is blended to promote curing reaction of the epoxy resins of Components (A) and (B) with the curing agent of Component (C). By using such Component (E), it is possible to firmly cure without being uncured during the encapsulating molding and the glass transition temperature of the cured product can be made high while improving storage stability of the thermosetting epoxy resin sheet for encapsulating a semiconductor of the present invention. In particular, by having a hydroxymethyl group, storage stability can be improved whereas it is an imidazole-based curing accelerator.

The imidazole-based curing accelerator of Component (E) is preferably a structure represented by the following general formula (1),

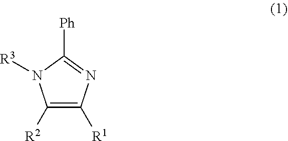

wherein, each of R¹ and R² independently represents any of a hydrogen atom, a methyl group, an ethyl group, a hydroxymethyl group or a phenyl group, at least one of them is a hydroxymethyl group; R³ represents a hydrogen atom, a methyl group, an ethyl group, a phenyl group or an allyl group; and Ph represents a phenyl group.

Examples of the imidazole-based curing accelerator of Component (E) include a commercially available product such as 2PHZ-PW (2-phenyl-4,5-dihydroxymethylimidazole, manufactured by Shikoku Chemicals Corporation), 2P4MHZ-PW (2-phenyl-4-methyl-5-hydroxymethylimidazole, manufactured by Shikoku Chemicals Corporation), and the like, and these can be used.

An amount of Component (E) is preferably 0.05 to 6 parts by mass, particularly preferably 0.1 to 5 parts by mass relative to the sum of 100 parts by mass of Components (A), (B), and (C). If it is 0.05 to 6 parts by mass, there is no fear of worsening the balance between heat resistance and moisture resistance of the cured product of the composition, or the curing rate during molding becomes extremely slow or fast.

Next, any of the following optional components can be blended to the composition as the material of the thermosetting epoxy resin sheet for encapsulating a semiconductor of the present invention, in addition to the Components (A) to (E).

### (F) Mold-Releasing Agent

In the composition which can be a material of the thermosetting epoxy resin sheet for encapsulating a semiconductor of the present invention, a mold-releasing agent may be blended as Component (F). The mold-releasing agent of Component (F) is to be blended to heighten mold-releasability at the time of molding. Examples of such Component (F) include natural wax such as carnauba wax and rice wax, and synthetic wax such as acid wax, polyethylene wax and fatty acid ester, and carnauba wax is preferable from the viewpoint of mold-releasability.

An amount of Component (F) to be blended is preferably 0.05 to 5.0 parts by mass, particularly preferably 0.4 to 3.0 parts by mass relative to the sum of 100 parts by mass of Component (A), Component (B), and Component (C). If the blended amount is 0.05 part by mass or more, there is no fear of not obtaining sufficient mold-releasability, or generating overloading during melt-kneading at the time of manufacture, while if it is 5.0 parts by mass or less, there is no fear of oozing failure or adhesion failure or the like.

### (G) Flame Retardant

In the thermosetting epoxy resin sheet for encapsulating a semiconductor of the present invention, a flame retardant may be blended as Component (G) for enhancing flame retardancy.

Such Component (G) is not particularly limited and conventionally known materials can be used. Examples thereof include a phosphazene compound, a silicone compound, talc supporting zinc molybdate thereon, zinc oxide supporting zinc molybdate thereon, aluminum hydroxide, magnesium hydroxide, molybdenum oxide, antimony trioxide, or the like, and they may be used singly, or in a combination of two or more kinds. An amount of Component (G) to be added is preferably 2 to 20 parts by mass, more preferably 3 to 10 parts by mass relative to the sum of 100 parts by mass of Component (A), Component (B), and Component (C).

### (H) Ion-Trapping Agent

In the thermosetting epoxy resin sheet for encapsulating a semiconductor of the present invention, an ion-trapping agent can be blended in order to prevent deterioration of reliability due to ionic impurities.

Such Component (H) is not particularly limited and conventionally known materials can be used. Examples thereof include hydrotalcites, bismuth hydroxide compounds, rare earth oxides, or the like. They may be used singly, or in a combination of two or more kinds. An amount of Component (H) to be added is preferably 0.5 to 10 parts by mass, more preferably 1.5 to 5 parts by mass relative to the sum of 100 parts by mass of Component (A), Component (B), and Component (C).

### (I) Coupling Agent

In the thermosetting epoxy resin sheet for encapsulating a semiconductor of the present invention, a coupling agent such as a silane coupling agent, a titanate coupling agent, or the like can be blended in order to strengthen bonding strength between the resin components of Component (A), Component (B), and Component (C) and (D) the inorganic filler, or to increase adhesion to a silicon wafer or an organic substrate, and among them, a silane coupling agent is preferable.

Examples of such a coupling agent include an epoxy functional alkoxysilane such as γ-glycidoxypropyltri-methoxysilane, γ-glycidoxypropylmethyldiethoxysilane, β-(3,4-epoxycyclohexyl)ethyltrimethoxysilane, and the like, an amino functional alkoxysilane such as N-β-(aminoethyl)-γ-aminopropyltrimethoxysilane, γ-aminopropyltriethoxysilane, N-phenyl-γ-aminopropyltrimethoxysilane, and the like, a mercapto functional alkoxysilane such as γ-mercaptopropyltrimethoxysilane, and the like, and an amine functional alkoxysilane such as γ-aminopropyltrimethoxysilane, N-2-(aminoethyl)-3-amino-propyltrimethoxysilane, and the like.

An amount of the coupling agent to be blended for the surface treatment and the surface treatment method are not particularly limited, and the treatment may be carried out in accordance with a conventional method. In addition, as mentioned above, the inorganic filler may be previously treated with the coupling agent, or the coupling agent may be added to the composition when the resin components of Component (A), Component (B), and Component (C) and the inorganic filler of Component (D) are mixed and kneaded, and the composition may be mixed and kneaded while subjecting to surface treatment thereof.

An amount of Component (I) to be added is preferably 0.1 to 8.0 parts by mass, particularly preferably 0.5 to 6.0 parts by mass relative to 100 parts by mass of the sum of Component (A), Component (B), and Component (C). If it is 0.1 part by mass or more, adhesion effect to the substrate can be sufficiently obtained, while if it is 8.0 parts by mass or less, there is no fear of extremely lowering viscosity to be a cause of voids.

### <Other Additives>

To the thermosetting epoxy resin sheet for encapsulating a semiconductor of the present invention, various additives can be further blended, if necessary. For example, for the purpose of improving the properties of the resin, organopolysiloxane, silicone oil, a thermoplastic resin, a thermoplastic elastomer, organic synthetic rubber, or an additive such as an antioxidant, a light stabilizer and the like, and from the viewpoint of coloring, a pigment such as carbon black may be added and blended.

If necessary, an epoxy resin other than the above Components (A) and (B) can be used in combination. Examples of the epoxy resin include a non-crystalline bisphenol A type epoxy resin, a non-crystalline bisphenol F type epoxy resin, a biphenol type epoxy resin such as a 3,3′,5,5′-tetramethyl-4,4′-biphenol type epoxy resin, and a 4,4′-biphenol type epoxy resin, an epoxy resin in which an aromatic ring of a phenol novolac type epoxy resin, a cresol novolac type epoxy resin, a bisphenol A novolac type epoxy resin, a naphthalene diol type epoxy resin, a tetrakisphenylol ethane type epoxy resin, or a phenol dicyclopentadiene novolac type epoxy resin is hydrogenated, an alicyclic epoxy resin, a silicone-modified epoxy resin, and the like.

### Method for Manufacturing Thermosetting Epoxy Resin Sheet for Encapsulating Semiconductor

As the method for manufacturing the thermosetting epoxy resin sheet for encapsulating a semiconductor of the present invention, there may be mentioned a T die extrusion method in which the epoxy resins of Components (A) and (B), the phenol curing agent of Component (C), the inorganic filler of Component (D), the curing accelerator of Component (E), and other additives are mixed at a predetermined composition ratio, after these are sufficiently and uniformly mixed by a mixer or the like, and then extruded by using a biaxial extruder having a T-die installed at the tip thereof.

As others, it can be obtained by subjecting to melt mixing treatment with a hot roll, a kneader, an extruder or the like, followed by cooling and solidification, and pulverization to an appropriate size, and the pulverized product of the obtained thermosetting epoxy resin composition is melted by heating at 70 to 120° C. between pressure members to mold it into a sheet shape.

The thermosetting epoxy resin sheet for encapsulating a semiconductor of the present invention thus obtained has a thickness of preferably 0.1 to 5.0 mm, and more preferably 0.15 to 3.0 mm.

In order to suitably use the thermosetting epoxy resin sheet for encapsulating a semiconductor of the present invention for encapsulating a semiconductor, in the resin sheet, it is preferable that a glass transition temperature of a cured product obtained by subjecting to pressure molding with a molding pressure of 6.9 N/mm², at 175° C. for 180 seconds, and then, secondary curing at 180° C. for 4 hours, and measured by thermomechanical analysis (TMA) is 150° C. or higher, more preferably 155° C. or higher. If the glass transition temperature of the cured product is 150° C. or higher, the thermosetting epoxy resin sheet for encapsulating a semiconductor of the present invention becomes a encapsulating material having more excellent heat resistant reliability.

In the thermosetting epoxy resin sheet for encapsulating a semiconductor of the present invention thus obtained, a deflection amount of the sheet in the three-point bending test in the uncured state is preferably 30 mm or more, more preferably 40 to 100 mm.

The three-point bending test referred to in the present invention is to apply the measurement method of bending strength described in JIS K 6911: 2006 mutatis mutandis. Specifically, as a test piece, a test piece having a length of 100 mm, a height of 1.0 mm, and a width of 10 mm is used, and loaded at a load speed of 2 ram/min, and the deflection amount is to obtain from the load-deflection curve measured according to the conditions mentioned in the standard with regard to the other conditions.

When such a thermosetting epoxy resin sheet for encapsulating a semiconductor of the present invention is employed, it becomes a thermosetting epoxy resin sheet for encapsulating a semiconductor which is excellent in flexibility in a state before curing, and good in handling property, while maintaining a high glass transition temperature after curing, and also excellent in storage stability and moldability.

### <Semiconductor Apparatus>

Also, in the present invention, there is provided a semiconductor apparatus in which a semiconductor device(s) is/are encapsulated by the thermosetting epoxy resin sheet for encapsulating a semiconductor of the present invention.

When such a semiconductor apparatus is employed, it becomes a semiconductor apparatus in which the semiconductor device(s) is/are well encapsulated, and is free from voids, wire flow, and die shift.

### <Method for Manufacturing Semiconductor Apparatus>

Also, in the present invention, there is provided a method for manufacturing a semiconductor apparatus in which a semiconductor device(s) is/are encapsulated by the thermosetting epoxy resin sheet for encapsulating a semiconductor.

The semiconductor apparatus of the present invention can be manufactured by encapsulating a semiconductor device(s) by compression molding or lamination molding using the thermosetting epoxy resin sheet for encapsulating a semiconductor of the present invention. When the compression molding is to be carried out, for example, it can be carried out with a compression molding machine at a molding temperature of 120 to 190° C. for a molding time of 30 to 600 seconds, preferably a molding temperature of 130 to 160° C. for a molding time of 120 to 450 seconds. Further, in either of the molding methods, post-curing may be carried out at 140 to 185° C. for 0.5 to 20 hours.

As others, encapsulating may be carried out by placing the thermosetting epoxy resin sheet for encapsulating a semiconductor of the present invention on a substrate on which a semiconductor device(s) is/are mounted, and melting the sheet on a hot plate at 80 to 150° C. for 30 to 240 minutes to follow the substrate. Further, encapsulating may be carried out using a pressure oven by softening and melting the sheet of the present invention while heating under pressure and/or under reduced pressure to encapsulate the semiconductor device(s).

When such a method for manufacturing a semiconductor apparatus is employed, it is possible to further improve adhesiveness between the thermosetting epoxy resin sheet for encapsulating a semiconductor following the shape of the semiconductor device(s) by softening and melting and the semiconductor device(s).

### EXAMPLE

In the following, the present invention will be explained more specifically by showing Examples and Comparative examples, but the present invention is not limited to the following Examples.

The raw materials used in Examples and Comparative examples are shown below.

(A) Bisphenol a Type Epoxy Resin and/or Bisphenol F Type Epoxy Resin Each Having Crystallinity
(A-1): Crystalline bisphenol A type epoxy resin (YL-6810: trade name, manufactured by Mitsubishi Chemical Corporation, epoxy equivalent: 170, melting point: 45° C.)
(B) Polyfunctional Type Epoxy Resin which is Solid at 25° C. and Other than Component (A)
(B-1): Trisphenol methane type epoxy resin (EPPN-502H: manufactured by Nippon Kayaku Co., Ltd., epoxy equivalent: 168, softening point: 60° C., the following formula),

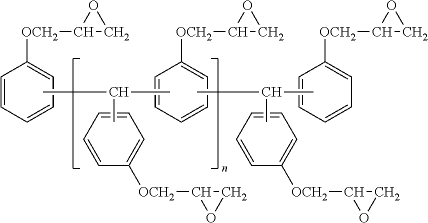

wherein, a repeating unit “n” is a number of 1 or more and satisfying the above epoxy equivalent.

(B′) Epoxy resin other than Component (A) and Component (B)
(B′-1): Solid bisphenol A type epoxy resin (jER-1001: manufactured by Mitsubishi Chemical Corporation, epoxy equivalent: 475, softening point: 64° C.)
(B′-2): Cresol novolac type epoxy resin (EPICLON N-670: manufactured by DIC Corporation, epoxy equivalent: 210, softening point: 73° C.)
(B′-3): Biphenyl type epoxy resin (YX-4000: manufactured by Mitsubishi Chemical Corporation, epoxy equivalent: 186, melting point: 105° C.)

### (C) Phenol Compound Having Two or More Phenolic Hydroxyl Groups in One Molecule

(C-1): Phenolic resin (DL-92: manufactured by Meiwa Plastic Industries Ltd., hydroxyl equivalent: 107)

### (D) Inorganic Filler

(D-1): Fused spherical silica (CS-6103 53C2, manufactured by Tatsumori Ltd., average particle size: 10 μm)

### (E) Imidazole-Based Curing Accelerator Having Melting Point of 170° C. or Higher, and One or Two Hydroxymethyl Groups in One Molecule

(E-1): 2-Phenyl-4,5-dihydroxymethylimidazole (2PHZ-PW, melting point: 170° C. or higher (decomposed at 230° C.), manufactured by Shikoku Chemicals Corporation)
(E-2): 2-Phenyl-4-methyl-5-hydroxymethylimidazole (2P4MHZ-PW, melting point: 170° C. or higher (decomposed at 191 to 195° C.), manufactured by Shikoku Chemicals Corporation)
(E′) Curing Accelerator Other than Component (E)
(E′-1): 2-Phenyl-4-methylimidazole (2P4MZ, melting point: 174 to 184° C., manufactured by Shikoku Chemicals Corporation)
(E′-2): Triphenylphosphine (TPP, manufactured by Hokko Chemical Industry Co., Ltd.)
(E′-3): Aliphatic dimethyl urea (U-CAT 3513N, manufactured by San-Apro Ltd.)

### (F) Mold-Releasing Agent

(F-1) Carnauba wax (TOWAX-131: manufactured by Toa Kasei Ltd.)

### (G) Flame Retardant

(G-1): zinc oxide supporting zinc molybdate (KEMGARD 911C: manufactured by Sherwin-Williams)

### (H) Ion-Trapping Agent

(H-1): Hydrotalcite compound (DHT-4C: manufactured by Kyowa Chemical Industry Co., Ltd.)

### (I) Coupling Agent

(I-1): Silane coupling agent: 3-mercaptopropyltrimethoxysilane (KBM-803: manufactured by Shin-Etsu Chemical Co., Ltd.)

### Examples 1 to 4 and Comparative Examples 1 to 8

With the formulation (parts by mass) shown in Tables 1 and 2, the materials were pre-mixed by a Henschel mixer beforehand, and then, extruded using a biaxial extruder having a T-die to obtain a sheet state epoxy resin composition having a width of 300 mm and a thickness of 0.5 mm.

### [Minimum Melt Viscosity and Storage Stability Test]

Using a Koka-type flow tester (manufactured by Shimadzu Corporation, product name: Flow Tester CFT-500 Model), and using a nozzle with a diameter of 1 mm under a pressure of 25 kgf, a minimum melt viscosity of each of the thermosetting epoxy resin sheet for encapsulating a semiconductor was measured at a temperature of 175° C. Further, each of the thermosetting epoxy resin sheet for encapsulating a semiconductor was placed in a thermostat set at 40° C., and the minimum melt viscosity after standing for 72 hours was also measured under the same conditions. The results are shown in Table 1 and Table 2.

### [Glass Transition Temperature]

Using a metal mold conforming to the EMMI standard, the thermosetting epoxy resin composition was cured under a molding temperature of 175° C., a molding pressure of 6.9 N/mm² and a molding time of 180 seconds, and post-cured at 180° C. for 4 hours. The glass transition temperature and the thermal expansion coefficient of the test piece prepared from the post-cured cured product were measured with TMA (TMA8310, manufactured by Rigaku Corporation).

After setting the temperature raising program to a temperature raising rate of 5° C./min, and setting a constant load of 49 mN to be applied to the test piece which is a cured product by post-curing, and dimensional change of the test piece was measured between 25° C. and 300° C. The relationship between the dimensional change and the temperature is plotted on a graph. From the graph of the dimensional change and the temperature thus obtained, the glass transition temperatures in Examples and Comparative examples were obtained. The results are shown in Table 1 and Table 2.

### [Deflection Amount of Sheet]

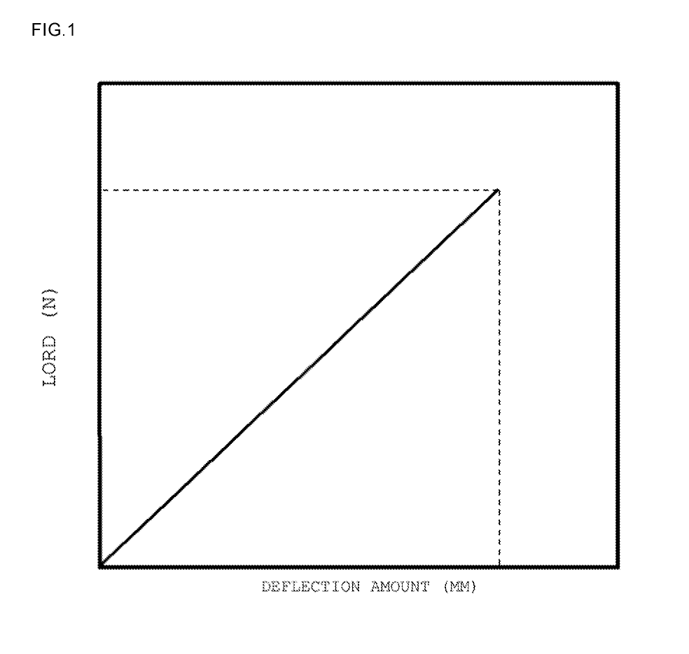

A thermosetting epoxy resin sheet for encapsulating a semiconductor in an uncured state with a length of 100 mm, a width of 10 mm, and a thickness of 1.0 mm was prepared, and this sheet was, as the three-point bending test, pressed at a load speed of 2 ram/min in accordance with JIS K 6911: 2006 standard at room temperature (25° C.), and a deflection amount was measured from the load-deflection amount curve as shown in FIG. 1. The results are shown in Table 1 and Table 2.

### [Moldability of Sheet]

A thermosetting epoxy resin sheet for encapsulating a semiconductor manufactured at a thickness of 0.5 mm by a T-die extrusion method was cut into a diameter of 150 mm (6 inches), set on a silicon wafer having a diameter of 200 mm (8 inches) and a thickness of 725 μm, and a release film made of PET was further set on the thermosetting epoxy resin sheet for encapsulating a semiconductor. This material was cured and encapsulated by vacuum compression molding using a vacuum press set so as to cure at 150° C. for 300 seconds. Thereafter, the release film was peeled off, and the filling property and appearance were confirmed.

### (Filling Property)

Good filling without problems was marked with good, and those with unfilled parts were marked with bad, and these were shown in Table 1 and Table 2.

### (Appearance)

Those having beautiful appearance were marked with good, and those with problems in appearance such as flow marks were marked with bad, and these were shown in Table 1 and Table 2.

TABLE 1

| Composition blended table | | | Examples | | | |
|---|---|---|---|---|---|---|
| (part by mass) | | | 1 | 2 | 3 | 4 |
| (A) | Epoxy resin | A-1 | 16.0 | 25.5 | 16.0 | 25.5 |
| (B) | Epoxy resin other | B-1 | 47.5 | 38.0 | 47.5 | 38.0 |
| | than Component | | | | | |
| | (A) | | | | | |
| (B′) | Epoxy resin other | B′-1 | — | — | — | — |
| | than Components | B′-2 | — | — | — | — |
| | (A) and (B) | B′-3 | — | — | — | — |
| (C) | Phenol compound | C-1 | 36.5 | 36.5 | 36.5 | 36.5 |
| (D) | Inorganic filler | D-1 | 600.0 | 600.0 | 600.0 | 600.0 |
| (E) | Specific curing | E-1 | 0.5 | 0.5 | — | — |
| | accelerator | E-2 | — | — | 0.5 | 0.5 |
| (E′) | Other curing | E′-1 | — | — | — | — |
| | accelerator | E′-2 | — | — | — | — |
| | | E′-3 | — | — | — | — |
| (F) | Mold-releasing | F-1 | 1.0 | 1.0 | 1.0 | 1.0 |
| | agent | | | | | |
| (G) | Frame retardant | G-1 | 10.0 | 10.0 | 10.0 | 10.0 |
| (H) | Ion trapping | H-1 | 3.0 | 3.0 | 3.0 | 3.0 |
| | material | | | | | |
| (I) | Coupling agent | I-1 | 0.5 | 0.5 | 0.5 | 0.5 |
| Evaluation | Initial minimum melt | | 15.0 | 16.0 | 16.2 | 15.3 |
| results | viscosity (Pa · s) | | | | | |
| | Minimum melt viscosity (Pa · s) | | 16.1 | 17.9 | 20.1 | 25.6 |
| | after 40° C. for 72 hours | | | | | |
| | Glass transition | | 165 | 158 | 161 | 155 |
| | temperature (° C.) | | | | | |
| | Sheet deflection amount | | 32 | 53 | 29 | 49 |
| | (mm) before curing | | | | | |
| | Moldability | Filling | good | good | good | good |
| | | property | | | | |
| | | Appearance | good | good | good | good |

TABLE 2

| Composition blended table | | | Comparative Examples | | | |
|---|---|---|---|---|---|---|
| (part by mass) | | | 1 | 2 | 3 | 4 |
| (A) | Epoxy resin | A-1 | 63.9 | 16.0 | 16.0 | 16.0 |
| (B) | Epoxy resin other | B-1 | — | 47.5 | 47.5 | 47.5 |
| | than Component (A) | | | | | |
| (B′) | Epoxy resin other | B′-1 | — | — | — | — |
| | than Components | B′-2 | — | — | — | — |
| | (A) and (B) | B′-3 | — | — | — | — |
| (C) | Phenol compound | C-1 | 36.1 | 36.5 | 36.5 | 36.5 |
| (D) | Inorganic filler | D-1 | 600.0 | 600.0 | 600.0 | 600.0 |
| (E) | Specific curing | E-1 | 0.5 | — | — | — |
| | accelerator | E-2 | — | — | — | — |
| (E′) | Other curing | E′-1 | — | 0.5 | — | — |
| | accelerator | E′-2 | — | — | 0.5 | — |
| | | E′-3 | — | — | — | 2.0 |
| (F) | Mold-releasing | F-1 | 1.0 | 1.0 | 1.0 | 1.0 |
| | agent | | | | | |
| (G) | Frame retardant | G-1 | 10.0 | 10.0 | 10.0 | 10.0 |
| (H) | Ion trapping | H-1 | 3.0 | 3.0 | 3.0 | 3.0 |
| | material | | | | | |
| (I) | Coupling agent | I-1 | 0.5 | 0.5 | 0.5 | 0.5 |
| Evaluation | Initial minimum melt | | 11.5 | 16.2 | 12.6 | 15.0 |
| results | viscosity (Pa · s) | | | | | |
| | Minimum melt viscosity (Pa · s) | | 12.6 | 49.0 | 13.9 | 17.5 |
| | after 40° C. for 72 hours | | | | | |
| | Glass transition | | 103 | 165 | — | 146 |
| | temperature (° C.) | | | | | |
| | Sheet deflection amount (mm) | | Not | 32 | 36 | 32 |
| | before curing | | broken | | | |
| | Moldability | Filling | good | good | — | good |
| | | property | | | | |
| | | Appearance | good | bad | — | good |

| | | |
|---|---|---|
| Remarks | Tack present, | Not cured |
| | there is | within |
| | difficulty in | molding |
| | handling | time |
| | property | |

| | |
|---|---|
| Composition blended table | Comparative Examples |

| (part by mass) | | | 5 | 6 | 7 | 8 |
|---|---|---|---|---|---|---|
| (A) | Epoxy resin | A-1 | 16.0 | 16.0 | 16.0 | — |
| (B) | Epoxy resin other | B-1 | — | — | — | 47.5 |
| | than Component (A) | | | | | |
| (B′) | Epoxy resin other | B′-1 | 63.0 | — | — | 20.8 |
| | than Components | B′-2 | — | 51.3 | — | — |
| | (A) and (B) | B′-3 | — | — | 49.6 | — |
| (C) | Phenol compound | C-1 | 21.0 | 32.7 | 34.4 | 31.7 |
| (D) | Inorganic filler | D-1 | 600.0 | 600.0 | 600.0 | 600.0 |
| (E) | Specific curing | E-1 | 0.5 | 0.5 | 0.5 | 0.5 |
| | accelerator | E-2 | — | — | — | — |
| (E′) | Other curing | E′-1 | — | — | — | — |
| | accelerator | E′-2 | — | — | — | — |
| | | E′-3 | 1.0 | 1.0 | 1.0 | 1.0 |
| (F) | Mold-releasing | F-1 | 1.0 | 1.0 | 1.0 | 1.0 |
| | agent | | | | | |
| (G) | Frame retardant | G-1 | 10.0 | 10.0 | 10.0 | 10.0 |
| (H) | Ion trapping | H-1 | 3.0 | 3.0 | 3.0 | 3.0 |
| | material | | | | | |
| (I) | Coupling agent | I-1 | 0.5 | 0.5 | 0.5 | 0.5 |
| Evaluation | Initial minimum melt | | 19.0 | 16.9 | 8.9 | 25.1 |
| results | viscosity (Pa · s) | | | | | |
| | Minimum melt viscosity (Pa · s) | | 19.0 | 20.3 | 11.1 | 29.2 |
| | after 40° C. for 72 hours | | | | | |
| | Glass transition | | 111 | 139 | 126 | 153 |
| | temperature (° C.) | | | | | |
| | Sheet deflection amount (mm) | | 45 | 39 | Not | — |
| | before curing | | | | broken | |
| | Moldability | Filling | good | good | good | good |
| | | property | | | | |
| | | Appearance | good | good | good | good |

| | |
|---|---|
| Remarks | Handling |
| | property is |
| | bad and |
| | cracked |
| | immediately |

As shown in Table 1, in Examples 1 to 4 using the thermosetting epoxy resin sheet for encapsulating a semiconductor of the present invention, the glass transition temperature is high and the deflection amount of the sheet is 30 mm or more in a state before curing, so that it is excellent in flexibility, good in handling property and small change in minimum melt viscosity after standing at 40° C. for 72 hours whereby it is also excellent in storage stability and good in moldability.

On the other hand, as shown in Table 2, in Comparative example 1, Component (B) was not used, so that tack was present and good handling property could not be obtained. Also, in Comparative examples 2 to 4, a curing accelerator other than Component (E) was used without using Component (E), so that high glass transition temperature and moldability could not be achieved at the same time. Further, in Comparative examples 5 to 7, an epoxy resin other than Component (B) was used without using Component (B), so that the glass transition temperature was not high. Moreover, in Comparative example 8, an epoxy resin other than Component (A) was used without using Component (A), so that good handling property could not be obtained.

From the above results, the thermosetting epoxy resin sheet of the present invention is excellent in flexibility in a state before curing, and good in handling property, while maintaining a high glass transition temperature after curing, and also excellent in storage stability and moldability, so it has been clarified that it is useful for semiconductor encapsulating applications.

It must be stated here that the present invention is not restricted to the embodiments shown by Examples. The embodiments shown by Examples are merely examples so that any embodiments composed of substantially the same technical concept as disclosed in the claims of the present invention and expressing a similar effect are included in the technical scope of the present invention.

1. A thermosetting epoxy resin sheet for encapsulating a semiconductor which comprises a composition containing
(A) a bisphenol A type epoxy resin and/or a bisphenol F type epoxy resin each having crystallinity,
(B) a polyfunctional type epoxy resin which is solid at 25° C. and other than the Component (A),
(C) a phenol compound having two or more phenolic hydroxyl groups in one molecule,
(D) an inorganic filler, and
(E) an imidazole-based curing accelerator having a melting point of 170° C. or higher, and one or two hydroxymethyl groups in one molecule,
being molded in a sheet form.

2. The thermosetting epoxy resin sheet for encapsulating a semiconductor according to claim 1, wherein the Component (B) is a trisphenol alkane type epoxy resin.

3. The thermosetting epoxy resin sheet for encapsulating a semiconductor according to claim 1, wherein the Component (E) is represented by the following general formula (1), 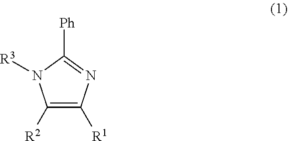
wherein, each of R¹ and R² independently represents any of a hydrogen atom, a methyl group, an ethyl group, a hydroxymethyl group or a phenyl group, at least one of them is a hydroxymethyl group; R³ represents a hydrogen atom, a methyl group, an ethyl group, a phenyl group or an allyl group; and Ph represents a phenyl group.

4. The thermosetting epoxy resin sheet for encapsulating a semiconductor according to claim 2, wherein the Component (E) is represented by the following general formula (1), 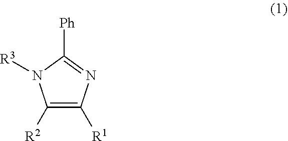
wherein, each of R¹ and R² independently represents any of a hydrogen atom, a methyl group, an ethyl group, a hydroxymethyl group or a phenyl group, at least one of them is a hydroxymethyl group; R³ represents a hydrogen atom, a methyl group, an ethyl group, a phenyl group or an allyl group; and Ph represents a phenyl group.

5. The thermosetting epoxy resin sheet for encapsulating a semiconductor according to claim 1, wherein the Component (D) contains silica.

6. The thermosetting epoxy resin sheet for encapsulating a semiconductor according to claim 2, wherein the Component (D) contains silica.

7. The thermosetting epoxy resin sheet for encapsulating a semiconductor according to claim 3, wherein the Component (D) contains silica.

8. The thermosetting epoxy resin sheet for encapsulating a semiconductor according to claim 4, wherein the Component (D) contains silica.

9. The thermosetting epoxy resin sheet for encapsulating a semiconductor according to claim 1, wherein the thermosetting epoxy resin sheet for encapsulating a semiconductor is a material in which a cured product thereof obtained by pressure molding with a molding pressure of 6.9 N/mm² at 175° C. for 180 seconds, and then, secondary curing at 180° C. for 4 hours, which has a glass transition temperature measured by thermomechanical analysis (TMA) of 150° C. or higher.

10. The thermosetting epoxy resin sheet for encapsulating a semiconductor according to claim 1, wherein the thermosetting epoxy resin sheet for encapsulating a semiconductor has a deflection amount of the sheet of 25 mm or more in a three-point bending test in an uncured state.

11. A semiconductor apparatus which comprises a semiconductor device(s) encapsulated by the thermosetting epoxy resin sheet for encapsulating a semiconductor according to claim 1.

12. A method for manufacturing a semiconductor apparatus which comprises encapsulating a semiconductor device(s) using the thermosetting epoxy resin sheet for encapsulating a semiconductor according to claim 1.

13. The method for manufacturing a semiconductor apparatus according to claim 12, wherein the semiconductor device(s) is/are encapsulated by softening and melting the sheet while heating under pressure and/or under reduced pressure when the semiconductor device(s) is/are encapsulated.
